(19) United States
(12) Patent Application Publication
(10) Pub. No.: US 2007/0231955 A1
(43) Pub. Date: Oct. 4, 2007

(54) Method For Packaging Flash Memory Cards

(76) Inventor: Chin-Tong Liu, Hsinchu (TW)

Correspondence Address: LIN & ASSOCIATES INTELLECTUAL PROPERTY, P.O. BOX 2339, SARATOGA, CA, 95070-0339, US

(21) Appl. No.: 11/420,806

(22) Filed: May 30, 2006

(30) Foreign Application Priority Data
Apr. 3, 2006 (TW) 095111772

(51) Int. Cl. H01L 21/00

(52) U.S. Cl. 438/106

(57) ABSTRACT

A packaging method for flash memory card is provided, including the steps of placing a circuit substrate in a mold, injecting thermosetting plastic material into the mold, moving to press the circuit substrate into the thermosetting plastic material for even distribution of thermosetting plastic material on the circumference and one side of the circuit substrate, heating to harden the thermosetting plastic material to form the final shape, and removing the final packaged memory card from the mold.

### FIELD OF THE INVENTION

The present invention generally relates to a packaging method for micro flash memory cards, and more specifically to a packaging method for flash memory cards using insert molding and thermosetting plastic.

### BACKGROUND OF THE INVENTION

As the digital products, such as mobile phones that can be used as a digital camera and MP3 player, are becoming popular, the consumer demands on the flash memory cards increase. The current types of the flash memory cards include compact flash (CF) card, smart media card (SMC), multimedia card (MMC), secure digital (SD) card, and memory stick (MS) card. The emergence of micro SD card and RS-MMC card further reduces the size of memory cards. Nevertheless, the new generation micro flash memory card, such as TransFlash (T-flash) takes the size reduction even one step further, while maintaining compatibility in specification with SD and minSD. In addition, the speed, functions, data exchange and security of T-flash all meets the demands of the consumers. Therefore, T-flash has become the choice of flash memory card for designs of mobile phones.

Because this type of memory card is small in size, for example, T-flash is 15×11×1 mm(L/W/H), the conventional manufacture process is to form a large area printed circuit board (PCB), and directly package the memory card on the surface of the PCB. As there are a plurality of memory sets on a single PCB, the conventional method includes a step to use water cutting or laser cutting to perform the final cutting to aquire the shape and the size of each individual memory card. However, the final cutting may damage the packaged memory card or creates cracks between the circuit substrate and the packaging material to reduce the yield rate. Therefore, it is imperative to develop a more effective packaging method.

### SUMMARY OF THE INVENTION

The present invention has been made to overcome the aforementioned drawback of conventional packaging methods. The primary object of the present invention is to provide a packaging method for flash memory cards using insert molding and thermosetting plastic to increase the manufacturing efficiency and yield rate.

Another object of the present invention is to provide a packaging method suitable for micro or ultra-thin flash memory cards. The method of the present invention is easier for the manufacturing of thin memory cards, and because the memory card is individually packaged, the cracks caused by the conventional packaging method are eliminated. Therefore, the sealing and the leakage prevention is better provided.

Yet another object of the present invention is to provide a packaging method that can lower the manufacturing cost and reduce the package defective. If a package defective is detected, the packaging material and the circuit substrate can be separated, and the circuit substrate can be re-packaged. In compared to the final cutting after the packaging in the conventional method, the present invention can effectively reduce the damage cost and improve the yield rate.

To achieve the above object, the present invention provides a method including the steps of placing a circuit substrate in a mold, injecting thermosetting plastic material into the mold, moving to press the circuit substrate into the thermosetting plastic material for even distribution of thermosetting plastic material on the circumference and one side of the circuit substrate, heating to harden the thermosetting plastic material to form the final shape, and removing the final packaged memory card from the mold.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a flowchart of the packaging method of the present invention;

FIG. 2 shows an enlarged cross-sectional view of the mold used in the packaging method of the present invention;

FIG. 3 shows an enlarged cross-sectional view of the mold with the circuit substrate inside the mold used in the packaging method of the present invention;

FIG. 4 shows an enlarged interior cross-sectional view of the mold with the thermosetting plastic material injected into the mold used in the packaging method of the present invention;

FIG. 5 shows an enlarged interior cross-sectional view of the mold with the thermosetting plastic material covering the circumference of the circuit substrate used in the packaging method of the present invention; and

FIG. 6 shows an enlarged cross-sectional view of the mold used in the packaging method of the present invention with thermosetting plastic material heated and hardened.

### DETAILED DESCRIPTION OF THE PREFERRED EMBODIMENTS

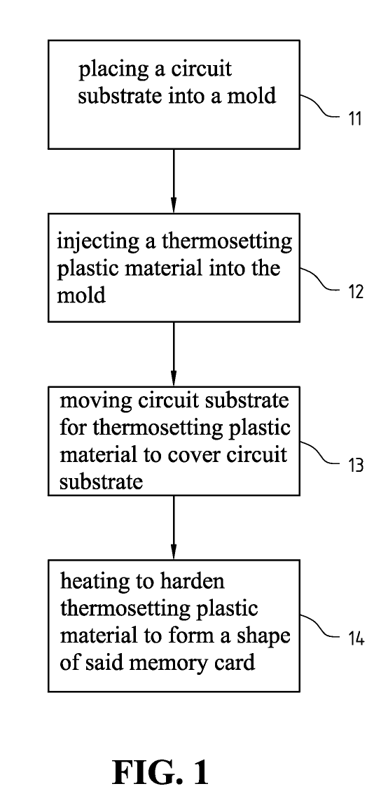

FIG. 1 shows a flowchart of the packaging method of the present invention. Step 11 is to place a circuit substrate that is already electronically connected into a mold for inject molding machine. Step 12 is to inject the thermosetting plastic material into the mold. Step 13 is to press the circuit substrate into the thermosetting plastic material so that the thermosetting plastic material can evenly cover the circumference and one side of the circuit substrate. Step 14 is to heat the thermosetting plastic material to a preset temperature and time so that the thermosetting plastic material is hardened and forms the final shape meeting the specification of a memory card. The circuit substrate is a circuit board that includes memory card circuits and electric connections. One side of the circuit substrate includes a plurality of electric contact parts, commonly known as the golden fingers. The electric contact parts must be exposed in the final packaged memory card for providing electric connection to the device. The other side of the circuit substrate includes the circuit and the chips, which will be covered and sealed by the method of the present invention. The final packaged shape of the memory card must meet the specifications of the memory card.

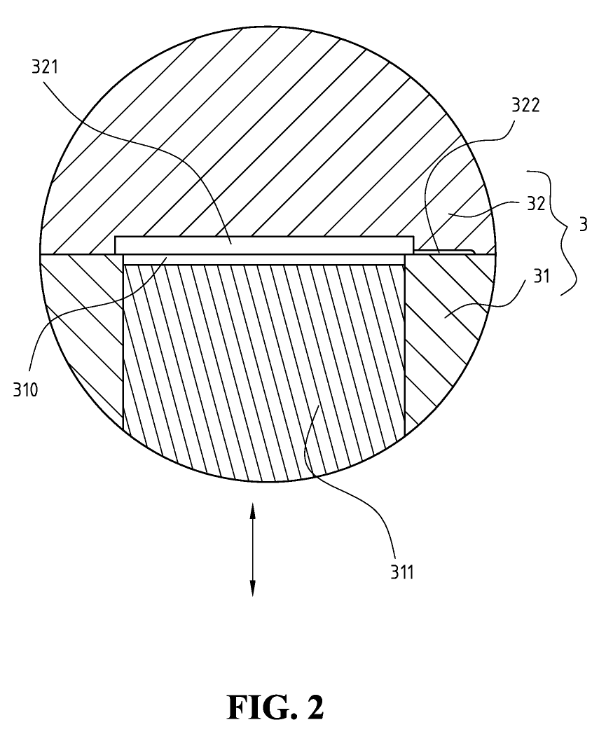

For clarity, the following embodiment uses a T-flash card as an example for explanation. However, the method of the present invention is not limited to the embodiment. Any other equivalent memory cards are also within the scope of the present invention. The following description refers to FIGS. 2-6. FIG. 2 shows an enlarged cross-sectional view of the mold used in the packaging method of the present invention. A mold 3 includes a main mold 31 and a secondary mold 32. Main mold 31 includes a moveable bottom compressor 311. Moveable bottom compressor 311 has the shape and the size matching the circuit substrate. The top of moveable bottom compressor and main mold 31 form a concave 310 for accommodating and holding the circuit substrate so that the circuit substrate will not drift when the thermosetting plastic material is injected into the mold. The bottom of secondary mold 32 includes a concave 321 corresponding to the location of moveable bottom compressor 311. Secondary mold 32 also includes an injection channel 322 for injecting thermosetting plastic material into concave 321. The shape and the size of concave 321 match the specification of a packaged memory card.

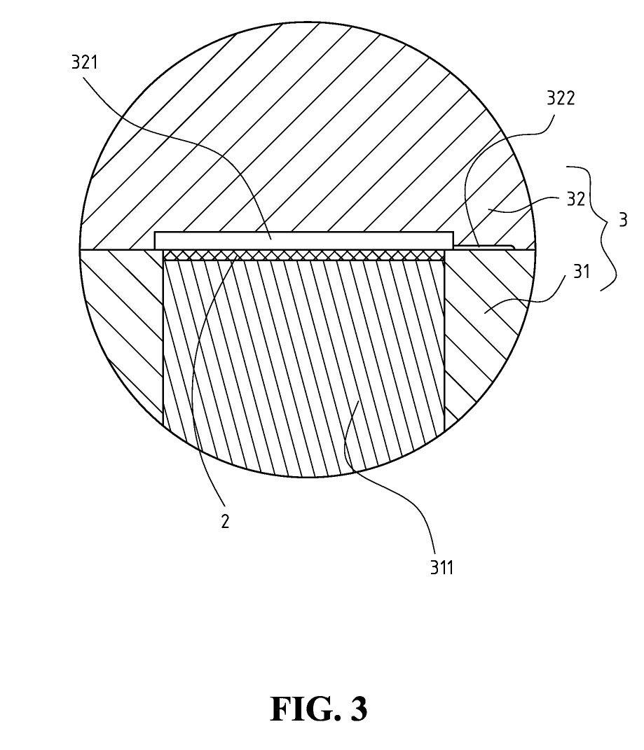

FIG. 3 shows an enlarged cross-sectional view of the mold with the circuit substrate inside the mold used in the packaging method of the present invention after step 11. A circuit substrate 2 is placed inside mold 3 at the location of concave 310 formed by the top of moveable bottom compressor 311 and mold 31.

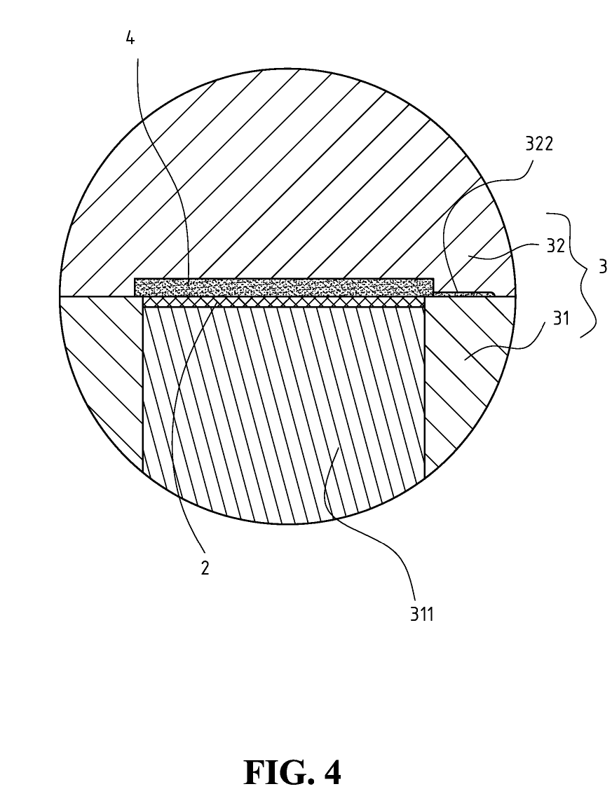

FIG. 4 shows an enlarged interior cross-sectional view of the mold with the thermosetting plastic material injected into the mold used in the packaging method of the present invention after step 12. Thermosetting plastic material 4 used in the embodiment is phenolic molding compound, or other equivalent material. The injection process pre-heats the phenolic molding compound into a viscous liquid. The viscous liquid is injected through injection channel 322 into concave 321 and fills concave 321. As circuit substrate 2 is held in concave 310 on the top of moveable bottom compressor 311, circuit substrate 2 will drift as the viscous liquid is injected.

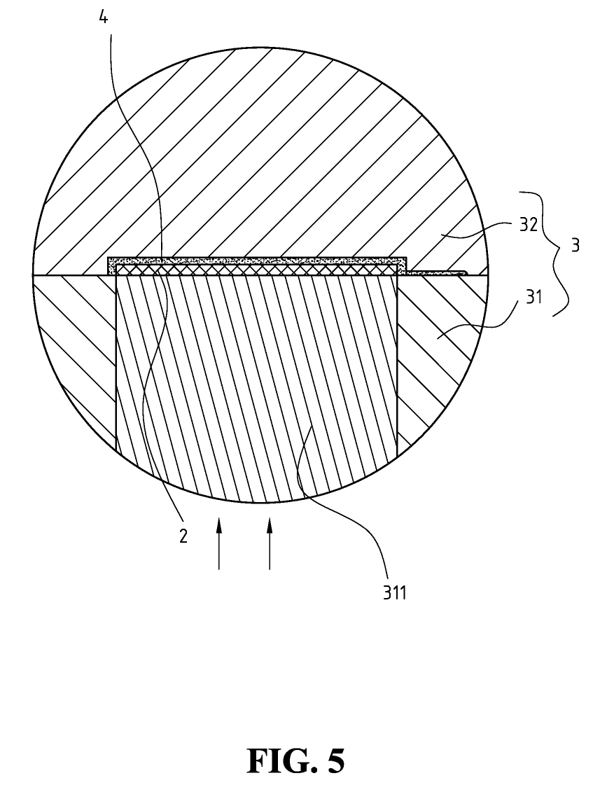

FIG. 5 shows an enlarged interior cross-sectional view of the mold with the thermosetting plastic material covering the circumference of the circuit substrate used in the packaging method of the present invention, after step 13. As concave 321 is filled with thermosetting plastic material 4, moveable bottom compressor 311 pushes up to compress circuit substrate 2 further into thermosetting plastic material 4 so that the top surface and the circumference of circuit substrate 2 is evenly covered with thermosetting plastic material 4 and the final thickness of the memory card is controlled to match the desired specification. For example, this embodiment uses T-flash card, which has a final thickness of 1 mm. The excessive thermosetting plastic material can overflow through injection channel 322 or the tiny millimeter gap between main mold 31 and secondary mold 32 for recycling. The compression of circuit substrate 2 into the viscous thermosetting plastic material makes the coverage more evenly distributed, as well as the pressure inside the mold.

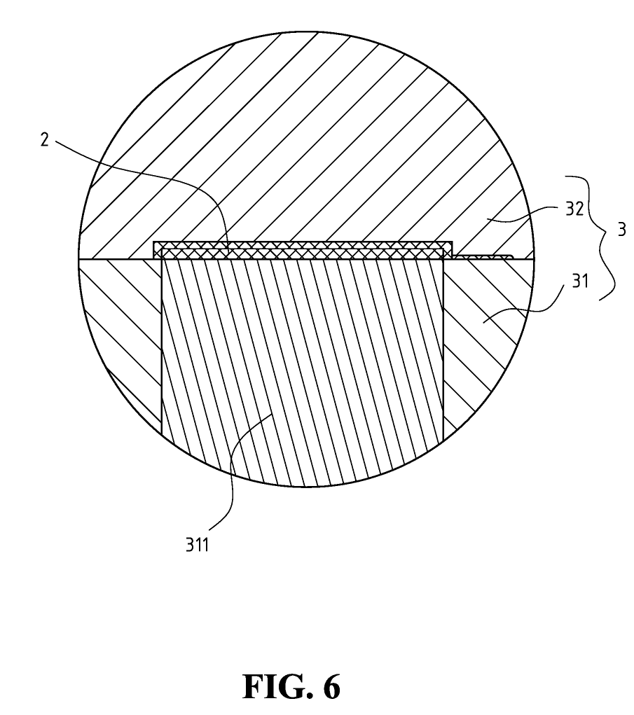

FIG. 6 shows an enlarged cross-sectional view of the mold used in the packaging method of the present invention with thermosetting plastic material heated and hardened, after step 14. The molding machine heats up the mold to the preset temperature and for a preset duration to harden the viscous thermosetting plastic material to form a monolithic structure with circuit substrate 2. Finally, the packaged memory card is removed from the mold, and the edges are trimmed and smoothed.

In summary, the packaging method of the present invention uses thermosetting plastic material in injection molding to form a monolithic structure of the memory card. The method is efficient, reduces the defective rate, and is suitable for micro and ultra-thin memory cards, such as T-flash, mini SD, and RS-MMC.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for packaging flash memory cards, comprising the steps of:
placing a circuit substrate into a mold;
injecting a thermosetting plastic material into said mold;
moving to press said circuit substrate into said thermosetting plastic material for said thermosetting plastic material to evenly cover the circumference and one side of said circuit substrate; and
heating said mold to harden said thermosetting plastic material to form a shape of said memory card.

2. The method as claimed in claim 1, wherein said circuit substrate is a printed circuit board (PCB) with complete electric connections.

3. The method as claimed in claim 1, wherein said thermosetting plastic material is phenolic molding compound.

4. The method as claimed in claim 1, wherein said injecting step pre-heats said thermosetting plastic material into a viscous liquid state.

5. The method as claimed in claim 1, wherein the injection of said thermosetting plastic material stops before said moving step to move said circuit substrate for pressing into said viscous thermosetting plastic material.

6. The method as claimed in claim 1, wherein said heating step heats said mold to a preset temperature for a preset duration to harden said thermosetting plastic material to form a monolithic structure with said circuit substrate.

7. The method as claimed in claim 1, wherein said packaging method is performed in an injection molding machine.

8. The method as claimed in claim 1, wherein said memory card is a T-flash card.

9. The method as claimed in claim 1, wherein said memory card is a mini SD card.

10. The method as claimed in claim 1, wherein said memory card is an RS-MMC card.
